(19) United States
(12) Patent Application Publication
(10) Pub. No.: US 2012/0190137 A1
(43) Pub. Date: Jul. 26, 2012

(54) CROSS SECTION OBSERVATION METHOD

(75) Inventors: Satomi ITO, Osaka-shi (JP); Takeyoshi MASUDA, Osaka-shi (JP)

(73) Assignee: SUMITOMO ELECTRIC INDUSTRIES, LTD., Osaka-shi (JP)

(21) Appl. No.: 13/012,585

(22) Filed: Jan. 24, 2011

(51) Int. Cl. H01L 21/66

(52) U.S. Cl. 438/14; 257/E21.53

(57) ABSTRACT

Provided is a cross section observation method, including the steps of: forming a marker layer at a base material, the marker layer having a conductivity different from that of another portion of the base material; forming a sample, by performing treatment on the base material at which the marker layer is formed; and detecting secondary electrons generated by emitting electrons to a cross section of the sample.

### BACKGROUND OF THE INVENTION

1. Field of the Invention

The present invention relates to a cross section observation method, and in particular to a cross section observation method capable of more accurately and easily determining whether or not treatment has been appropriately performed, by observing a cross section.

2. Description of the Background Art

For example, in a process of manufacturing semiconductor devices, it is important to appropriately perform treatment such as epitaxial growth, etching, and annealing. It is required to determine conditions for appropriately performing the treatment beforehand, from the viewpoint of improving efficiency of manufacturing semiconductor devices.

Whether or not treatment such as epitaxial growth, etching, and annealing has been appropriately performed can be determined by observing and comparing cross sections of a semiconductor crystal before and after the treatment.

As a cross section observation method for a semiconductor crystal as described above, a technique of observing a cross section of a semiconductor crystal using a SEM (scanning electron microscope) is often used (for example, see Japanese Patent Laying-Open No. 11-273613).

### SUMMARY OF THE INVENTION

However, in a conventional cross section observation method using a SEM, there has been a possibility that it is difficult to distinguish how a cross section of a semiconductor crystal changes before and after the treatment described above, and it is not possible to accurately determine whether or not the treatment described above has been appropriately performed.

In view of the above circumstances, one object of the present invention is to provide a cross section observation method capable of more accurately and easily determining whether or not treatment has been appropriately performed, by observing a cross section of a sample.

The present invention is directed to a cross section observation method, including the steps of: forming a marker layer at a base material, the marker layer having a conductivity different from that of another portion of the base material; forming a sample, by performing treatment on the base material at which the marker layer is formed; and detecting secondary electrons generated by emitting electrons to a cross section of the sample.

Preferably, in the cross section observation method according to the present invention, the above treatment is at least one selected from the group consisting of epitaxial growth, etching, and annealing.

Preferably, in the cross section observation method according to the present invention, the marker layer is formed by ion implantation.

Preferably, in the cross section observation method according to the present invention, the marker layer is formed by epitaxial growth.

Preferably, in the cross section observation method according to the present invention, the marker layer is formed at at least one of a top surface and an inside of the base material.

Preferably, in the cross section observation method according to the present invention, the marker layer forms a pattern.

Preferably, in the cross section observation method according to the present invention, a plurality of the marker layers are formed.

Preferably, in the cross section observation method according to the present invention, concaves and convexes are formed at a top surface of the base material before or after the step of forming the marker layer.

Preferably, in the cross section observation method according to the present invention, the marker layer is formed to have a conductivity type different from that of an adjacent region adjacent to the marker layer.

Preferably, in the cross section observation method according to the present invention, the marker layer is formed to have a conductivity type identical to that of an adjacent region adjacent to the marker layer, and have a dopant concentration not less than ten times a dopant concentration in the adjacent region.

According to the present invention, a cross section observation method capable of more accurately and easily determining whether or not treatment has been appropriately performed, by observing a cross section of a sample, can be provided.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic perspective view illustrating a portion of a process in Embodiment 1 as an example of a cross section observation method according to the present invention.

FIG. 2 is a schematic perspective view illustrating another portion of the process in Embodiment 1 as an example of the cross section observation method according to the present invention.

FIG. 3 is a schematic view illustrating another portion of the process in Embodiment 1 as an example of the cross section observation method according to the present invention.

FIG. 4 is a schematic cross sectional view illustrating another portion of the process in Embodiment 1 as an example of the cross section observation method according to the present invention.

FIG. 5 is a schematic cross sectional view illustrating a portion of a process in Embodiment 2 as an example of the cross section observation method according to the present invention.

FIG. 6 is a schematic cross sectional view illustrating another portion of the process in Embodiment 2 as an example of the cross section observation method according to the present invention.

FIG. 7 is a schematic cross sectional view illustrating a portion of a process in Embodiment 3 as an example of the cross section observation method according to the present invention.

FIG. 8 is a schematic cross sectional view illustrating another portion of the process in Embodiment 3 as an example of the cross section observation method according to the present invention.

FIG. 9 is a schematic cross sectional view illustrating a portion of a process in Embodiment 4 as an example of the cross section observation method according to the present invention.

FIG. 10 is a schematic cross sectional view illustrating another portion of the process in Embodiment 4 as an example of the cross section observation method according to the present invention.

FIG. 11 is a schematic cross sectional view illustrating another portion of the process in Embodiment 4 as an example of the cross section observation method according to the present invention.

FIG. 12 is a schematic cross sectional view illustrating a portion of a process in Embodiment 5 as an example of the cross section observation method according to the present invention.

FIG. 13 is a schematic cross sectional view illustrating another portion of the process in Embodiment 5 as an example of the cross section observation method according to the present invention.

FIG. 14 is a schematic cross sectional view illustrating another portion of the process in Embodiment 5 as an example of the cross section observation method according to the present invention.

FIG. 15 is a schematic cross sectional view illustrating a portion of a process in Embodiment 6 as an example of the cross section observation method according to the present invention.

FIG. 16 is a schematic cross sectional view illustrating another portion of the process in Embodiment 6 as an example of the cross section observation method according to the present invention.

FIG. 17 is a schematic cross sectional view illustrating a portion of a process in Embodiment 7 as an example of the cross section observation method according to the present invention.

FIG. 18 is a schematic cross sectional view illustrating another portion of the process in Embodiment 8 as an example of the cross section observation method according to the present invention.

### DESCRIPTION OF THE PREFERRED EMBODIMENTS

In the following, embodiments of the present invention will be described. Although a case where a semiconductor crystal is used as a base material will be described in the present embodiments, the present invention is not limited to the case where a semiconductor crystal is used as a base material. Further, in the drawings of the present invention, identical or corresponding parts will be designated by the same reference numerals.

### Embodiment 1

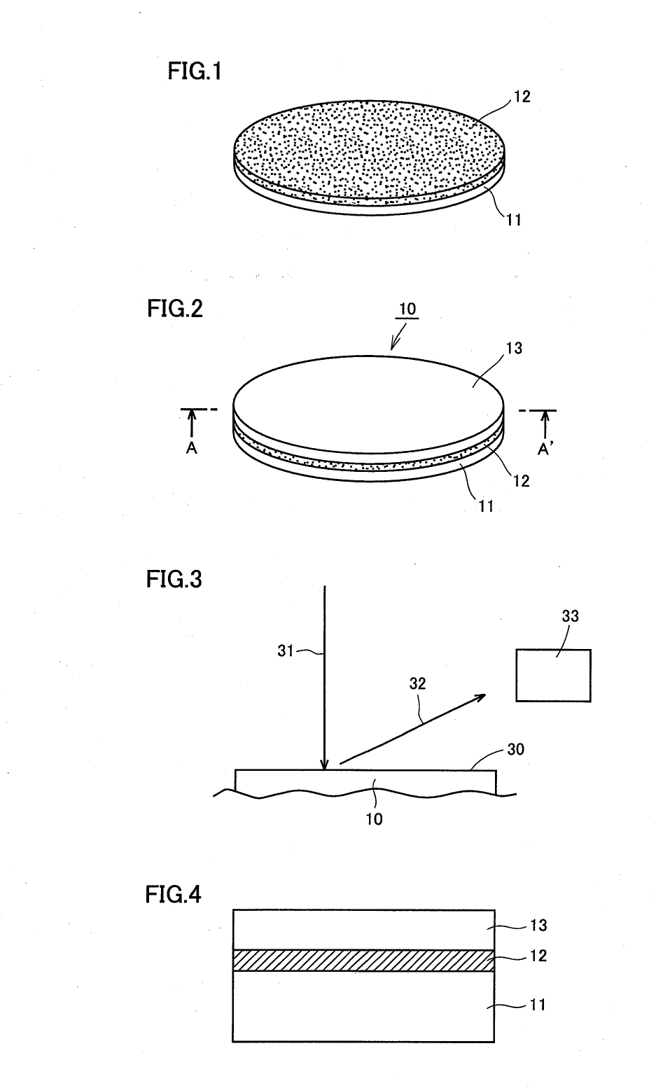

Hereinafter, Embodiment 1 as an example of a cross section observation method according to the present invention will be described with reference to FIGS. 1 to 4.

Firstly, as shown in the schematic perspective view of FIG. 1, a marker layer 12 is formed at a top surface of a base material 11 made of a semiconductor crystal.

Here, the semiconductor crystal used for base material 11 is not particularly limited, and, for example, a silicon carbide crystal or the like can be used.

Further, marker layer 12 is not particularly limited, as long as it is a layer having a conductivity different from that of a portion of base material 11 other than a portion at which marker layer 12 is formed.

Marker layer 12 can be formed, for example, by implanting ions of an n-type or p-type dopant in the top surface of base material 11 under conditions that enable the ions to be implanted in the top surface of base material 11, and the ion-implanted portion can serve as marker layer 12. Further, marker layer 12 can also be formed, for example, by epitaxially growing a semiconductor crystal layer having a composition different from that of base material 11 on the top surface of base material 11, and the epitaxially grown portion can serve as marker layer 12. Furthermore, marker layer 12 may be formed using the ion implantation described above and the epitaxial growth described above singly, or may be formed using both the ion implantation described above and the epitaxial growth described above.

Next, as shown in the schematic perspective view of FIG. 2, base material 11 is subjected to treatment for epitaxially growing a semiconductor crystal layer 13 on a surface of marker layer 12 formed at base material 11. Thereby, a sample 10 having a structure in which base material 11, marker layer 12, and semiconductor crystal layer 13 are arranged in this order is formed. Here, as semiconductor crystal layer 13, a semiconductor crystal made of a material identical to or different from that for the semiconductor crystal used for base material 11 may be used.

Then, sample 10 shown in FIG. 2 is cut out along A-A′ to expose an A-A′ vertical cross section. Here, although the cut-out of sample 10 is not particularly limited, it is preferably performed by cleavage. If sample 10 is cut out by cleavage, there is a tendency that the A-A′ vertical cross section of sample 10 can be exposed in a cleaner condition.

Subsequently, as shown in the schematic view of FIG. 3, electrons 31 are emitted to an A-A′ vertical cross section 30 of sample 10, and secondary electrons 32 generated by the emission of electrons 31 are detected by a secondary electron detector 33. By performing this step on an entire observation area of A-A′ vertical cross section 30 of sample 10 using, for example, a SEM (scanning electron microscope) or the like, A-A′ vertical cross section 30 of sample 10 can be observed for example in a SEM image or the like, based on a difference in the amount of secondary electrons 32 detected by secondary electron detector 33, or the like.

FIG. 4 shows a schematic view of an example of a SEM image obtained when A-A′ vertical cross section 30 of sample 10 is observed with a SEM. Here, in the SEM image, marker layer 12 is displayed in a color different from those of base material 11 and semiconductor crystal layer 13.

Generally, when electrons are emitted to a surface of a sample, secondary electrons (electrons ejected from the surface of the sample due to the emission of the electrons) are generated. By detecting the secondary electrons, a difference in conductivity at the surface of the sample can be observed based on a difference in the amount of the secondary electrons detected.

Thus, at a portion of base material 11, marker layer 12 having a conductivity different from that of the other portion of base material 11 is formed intentionally, and secondary electrons generated by emitting electrons to a cross section in which marker layer 12 is formed are detected. Thereby, when the cross section is observed for example in a SEM image, there is a clearer color contrast between marker layer 12 and a portion adjacent to marker layer 12.

For example, in this example, if the semiconductor crystal constituting base material 11 and the semiconductor crystal constituting semiconductor crystal layer 13 are of the same material, and marker layer 12 is not formed, a boundary between base material 11 and semiconductor crystal layer 13 is not clear, and thus it is difficult to accurately measure the thickness of epitaxially grown semiconductor crystal layer 13. However, if marker layer 12 is provided beforehand to base material 11 as in the present invention, a boundary between marker layer 12 and semiconductor crystal layer 13 can be seen more clearly based on color contrast in, for example, a SEM image or the like. Therefore, the thickness of epitaxially grown semiconductor crystal layer 13 can be measured more accurately.

Consequently, in Embodiment 1 as an example of the cross section observation method according to the present invention, whether or not the epitaxial growth treatment has been appropriately performed can be determined more accurately and easily, by observing the vertical cross section of sample 10.

### Embodiment 2

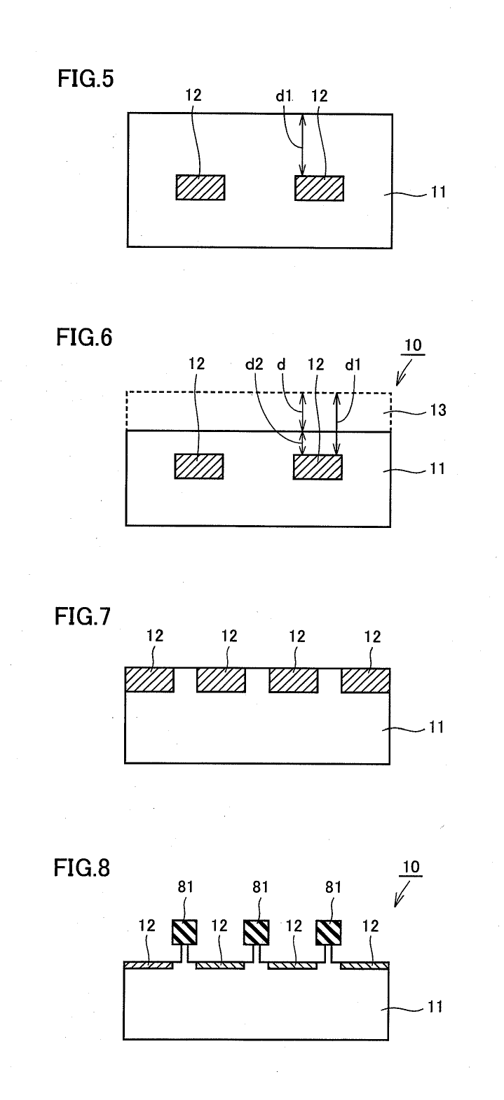

Hereinafter, Embodiment 2 as another example of the cross section observation method according to the present invention will be described with reference to FIGS. 5 and 6. Embodiment 2 is characterized in that the marker layer is formed partially at the inside of the base material.

Firstly, as shown in the schematic cross sectional view of FIG. 5, marker layer 12 is formed at a position having a depth of d1 from the top surface of base material 11. Here, marker layer 12 can be formed, for example, by implanting ions of an n-type or p-type dopant under conditions that enable the ions to be implanted in the top surface of base material 11, and thereafter epitaxially growing a semiconductor crystal layer having a composition identical to that of base material 11, to embed marker layer 12. Further, marker layer 12 can also be formed, for example, by implanting ions of an n-type or p-type dopant under conditions that enable the ions to be implanted in the inside of base material 11, and the ion-implanted portion can serve as marker layer 12.

Next, as shown in the schematic cross sectional view of FIG. 6, etching treatment is performed on base material 11 to remove a portion of base material 11 from the top surface of base material 11 in a thickness direction and form sample 10. A portion indicated by a broken line in. FIG. 6 represents the portion removed by the etching treatment described above.

Subsequently, as in Embodiment 1, electrons are emitted to a vertical cross section of sample 10 (cross section shown in FIG. 6), and secondary electrons generated by the emission of the electrons are detected by a secondary electron detector. By performing this step on the entire observation area of the vertical cross section of sample 10 using, for example, a SEM or the like, the vertical cross section of sample 10 is observed.

Also in this case, since marker layer 12 has a conductivity different from that of a portion of base material 11 adjacent to marker layer 12, marker layer 12 is displayed for example in a SEM image or the like, in a color different from that of the portion of base material 11 adjacent to marker layer 12. Therefore, a boundary between marker layer 12 and the portion of base material 11 adjacent to marker layer 12 can be seen more clearly, and thus a distance d2 between the top surface of base material 11 after the etching treatment described above and an uppermost surface of marker layer 12 can be measured accurately and easily.

Thus, an etching amount d in the etching treatment described above can be obtained by subtracting distance d2 after the etching treatment described above from a distance d1 between the top surface of base material 11 before the etching treatment described above and the uppermost surface of marker layer 12.

Consequently, in Embodiment 2 as another example of the cross section observation method according to the present invention, whether or not the etching treatment in the thickness direction has been appropriately performed on base material 11 can be determined more accurately and easily, by observing the vertical cross section of sample 10.

In the foregoing, distance d1 between the top surface of base material 11 before the etching treatment and the uppermost surface of marker layer 12 can be determined beforehand, for example, by fabricating base material 11 subjected to ion implantation by the same method and under the same conditions beforehand, and observing a vertical cross section of base material 11 using a SEM or the like.

### Embodiment 3

Hereinafter, Embodiment 3 as another example of the cross section observation method according to the present invention will be described with reference to FIGS. 7 and 8. Embodiment 3 is characterized in that the marker layer forms a pattern at the top surface of the base material.

Firstly, as shown in the schematic cross sectional view of FIG. 7, marker layer 12 is formed in a predetermined pattern at the top surface of base material 11. Here, the pattern formed by marker layer 12 is not particularly limited, and, for example, in this example, marker layer 12 is formed in a stripe pattern extending from a front side to a back side of the paper plane of FIG. 7. Further, marker layer 12 can be formed, for example, by placing an ion implantation mask formed in a predetermined pattern on the top surface of base material 11, and implanting ions of an n-type or p-type dopant in the top surface of base material 11 under conditions that enable the ions to be implanted in the top surface of base material 11. Thereby, marker layer 12 can be formed at a portion where the ion implantation mask is not formed, and the ion-implanted portion can serve as marker layer 12.

Next, as shown in the schematic cross sectional view of FIG. 8, a resist mask 81 is formed on base material 11, at an area other than the portion where marker layer 12 is formed at the top surface of base material 11, and thereafter the top surface of base material 11 is subjected to etching treatment (etching treatment in an up-down direction and a right-left direction in the paper plane of FIG. 8). Thereby, sample 10 is formed.

Subsequently, as in Embodiments 1 and 2, electrons are emitted to a vertical cross section of sample 10 (cross section shown in FIG. 8), and secondary electrons generated by the emission of the electrons are detected by a secondary electron detector. By performing this step on the entire observation area of the vertical cross section of sample 10 using, for example, a SEM or the like, the vertical cross section of sample 10 is observed.

Also in this case, since marker layer 12 has a conductivity different from that of a portion of base material 11 adjacent to marker layer 12, marker layer 12 is displayed for example in a SEM image or the like, in a color different from that of the portion of base material 11 adjacent to marker layer 12. Therefore, a boundary between marker layer 12 and the portion of base material 11 adjacent to marker layer 12 can be seen more clearly, and thus, for example, it can be recognized accurately and easily how much a side wall of the groove described above is inclined with respect to the top surface of base material 11.

Consequently, in Embodiment 3 as another example of the cross section observation method according to the present invention, whether or not the etching treatment in a width direction (etching treatment in the right-left direction in the paper plane of FIG. 8) has been appropriately performed on the top surface of base material 11 can be determined more accurately and easily, by observing the vertical cross section of sample 10.

### Embodiment 4

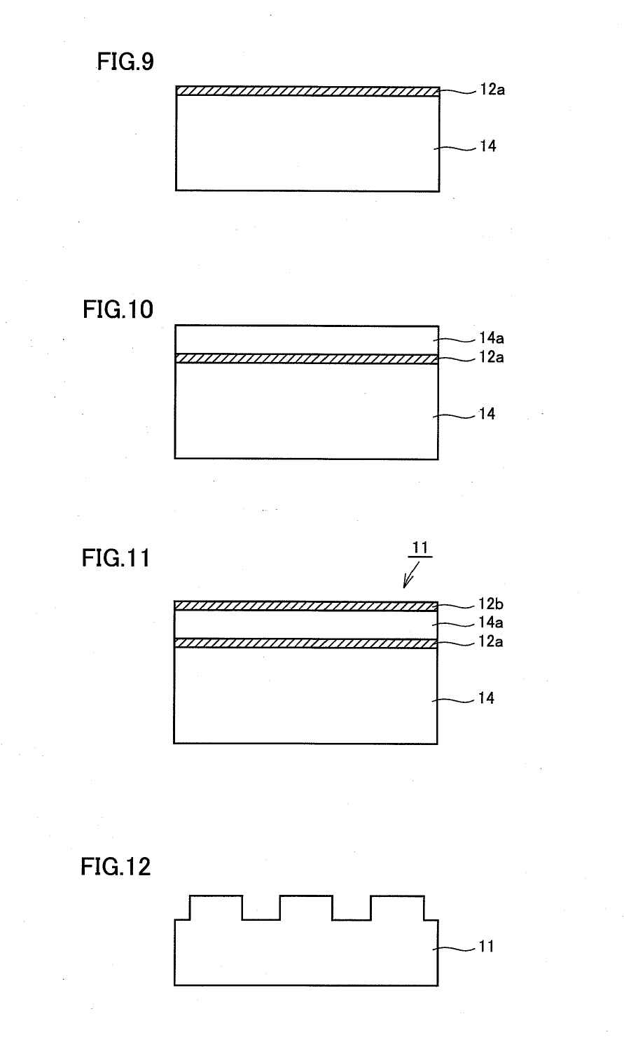

Hereinafter, Embodiment 4 as another example of the cross section observation method according to the present invention will be described with reference to FIGS. 9 to 11. Embodiment 4 is characterized in that the marker layer is formed at each of the inside and the top surface of the base material.

Firstly, as shown in the schematic cross sectional view of FIG. 9, on a top surface of a semiconductor crystal substrate 14, a semiconductor crystal layer having a composition different from that of substrate 14 is epitaxially grown, and the epitaxially grown portion is referred to as a marker layer 12a. A semiconductor crystal used for semiconductor crystal substrate 14 is not particularly limited, and, for example, a silicon carbide crystal or the like can be used.

Next, as shown in the schematic cross sectional view of FIG. 10, on a surface of marker layer 12a, a semiconductor crystal layer 14a made of a semiconductor crystal having a composition identical to that of semiconductor crystal substrate 14 is grown by epitaxial growth.

Subsequently, as shown in the schematic cross sectional view of FIG. 11, on a surface of epitaxially grown semiconductor crystal layer 14a, a semiconductor crystal layer having a composition different from that of semiconductor crystal substrate 14 and semiconductor crystal layer 14a is epitaxially grown, and the epitaxially grown portion is referred to as a marker layer 12b at a top surface. Thereby, base material 11 having a structure in which marker layer 12a is formed inside and marker layer 12b is formed at the top surface is formed.

Then, base material 11 in which marker layer 12a and marker layer 12b described above are formed is subjected to treatment in which an etching rate is substantially identical to an epitaxial growth rate and for which it is unpredictable whether the treatment functions as epitaxial growth or etching. Thereby, a sample is formed.

Subsequently, as in Embodiments 1 to 3, electrons are emitted to a vertical cross section of the sample, and secondary electrons generated by the emission of the electrons are detected by a secondary electron detector. By performing this step on the entire observation area of the vertical cross section of the sample using, for example, a SEM or the like, the vertical cross section of the sample is observed.

Also in this case, since marker layer 12a and marker layer 12b have a conductivity different from that of a portion adjacent to these marker layers, they are displayed for example in a SEM image or the like, in a color different from that of the portion adjacent to these marker layers. Thus, a boundary between marker layers 12a, 12b and the portion adjacent to these marker layers can be seen more clearly. Therefore, if the treatment has functioned as epitaxial growth, both marker layer 12a and marker layer 12b are observed, and thus an epitaxial growth amount can be measured by measuring a distance from a surface of marker layer 12b to an uppermost surface of base material 11 after the epitaxial growth. Further, if the treatment has functioned as etching, marker layer 12b is not observed and only marker layer 12a is observed, and thus an etching amount can be measured by measuring a distance from a surface of marker layer 12a to an uppermost surface of base material 11 after the etching, and subtracting the measured distance from a distance between an uppermost surface of marker layer 12b and the surface of marker layer 12a measured in advance before the etching.

Consequently, in Embodiment 4 as another example of the cross section observation method according to the present invention, whether epitaxial growth or etching has been performed on base material 11 can be determined more accurately and easily, by observing the vertical cross section of the sample. Further, if epitaxial growth has been performed, whether or not the treatment has been appropriately performed can be determined more accurately and easily based on the epitaxial growth amount (for example, film thickness), and if etching has been performed, whether or not the treatment has been appropriately performed can be determined more accurately and easily based on the etching amount.

### Embodiment 5

Hereinafter, Embodiment 5 as another example of the cross section observation method according to the present invention will be described with reference to FIGS. 12 to 14. Embodiment 5 is characterized in that concaves and convexes are formed at the top surface of the base material, and thereafter the marker layer is formed at the top surface of the base material.

Firstly, as shown in the schematic cross sectional view of FIG. 12, concaves and convexes are formed at the top surface of base material 11. Here, the concaves and convexes at the top surface of base material 11 can be formed, for example, by removing a portion of the flat top surface of base material 11 by etching.

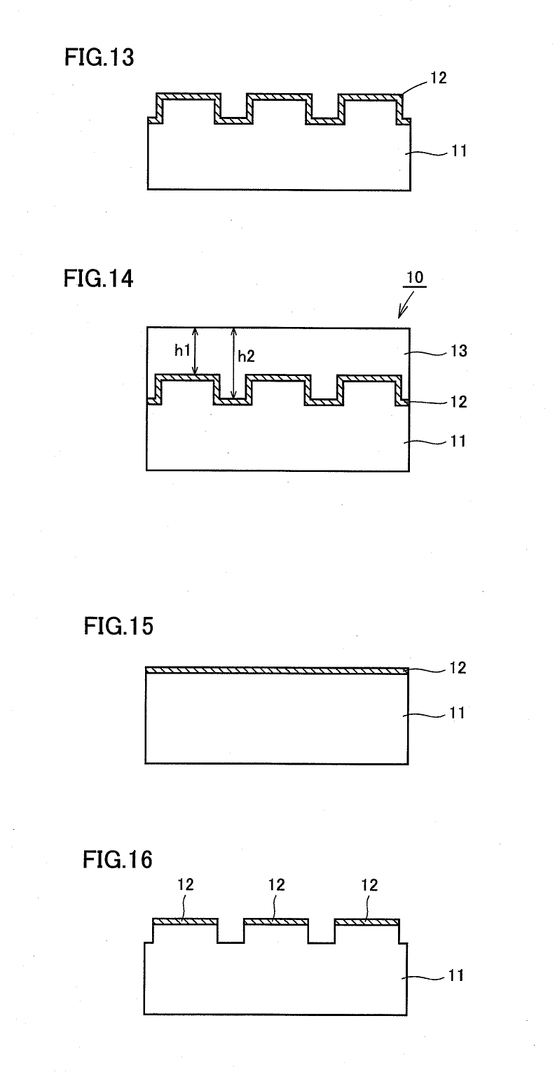

Next, as shown in the schematic cross sectional view of FIG. 13, marker layer 12 is formed at the top surface of base material 11 where the concaves and convexes are formed. Here, marker layer 12 can be formed, for example, by implanting ions of an n-type or p-type dopant in the top surface of base material 11 under conditions that enable the ions to be implanted in the top surface of base material 11 where the concaves and convexes are formed, and the ion-implanted portion can serve as marker layer 12.

Then, as shown in the schematic cross sectional view of FIG. 14, treatment for epitaxially growing semiconductor crystal layer 13 on marker layer 12 formed at the top surface of base material 11 having the concaves and convexes. Thereby, sample 10 is formed.

Subsequently, as in Embodiments 1 to 4, electrons are emitted to a vertical cross section of sample 10 (cross section shown in FIG. 14), and secondary electrons generated by the emission of the electrons are detected by a secondary electron detector. By performing this step on the entire observation area of the vertical cross section of sample 10 using, for example, a SEM or the like, the vertical cross section of sample 10 is observed.

For example, in this example, since a boundary between marker layer 12 and semiconductor crystal layer 13 can be seen clearly as a difference in color in, for example, a SEM image or the like, a thickness h1 of semiconductor crystal layer 13 grown on a convex portion of marker layer 12 and a thickness h2 of semiconductor crystal layer 13 grown on a concave portion of marker layer 12 can be measured more accurately.

Consequently, in Embodiment 5 as an example of the cross section observation method according to the present invention, whether or not the epitaxial growth treatment has been appropriately performed can be determined more accurately and easily, by observing the vertical cross section of sample 10.

### Embodiment 6

Hereinafter, Embodiment 6 as another example of the cross section observation method according to the present invention will be described with reference to FIGS. 15 and 16. Embodiment 6 is characterized in that the marker layer is formed at the top surface of the base material, and thereafter concaves and convexes are formed at the top surface of the base material.

Firstly, as shown in the schematic cross sectional view of FIG. 15, marker layer 12 is formed at the top surface of base material 11. Here, marker layer 12 can be formed, for example, by implanting ions of an n-type or p-type dopant in the top surface of base material 11 under conditions that enable the ions to be implanted in the top surface of base material 11, and the ion-implanted portion can serve as marker layer 12.

Next, as shown in the schematic cross sectional view of FIG. 16, concaves and convexes are formed at the top surface of base material 11 where marker layer 12 is formed. Here, the concaves and convexes at the top surface of base material 11 can be formed, for example, by removing a portion of the flat top surface of base material 11 by etching to a depth that is greater than the thickness of marker layer 12.

Then, base material 11 in which marker layer 12 described above is formed is subjected to epitaxial growth treatment performed in a relatively short time period. Thereby, a sample is formed.

Subsequently, as in Embodiments 1 to 5, electrons are emitted to a vertical cross section of the sample, and secondary electrons generated by the emission of the electrons are detected by a secondary electron detector. By performing this step on the entire observation area of the vertical cross section of the sample using, for example, a SEM or the like, the vertical cross section of the sample is observed.

Also in this case, since marker layer 12 has a conductivity different from that of a portion adjacent to marker layer 12, marker layer 12 is displayed for example in a SEM image or the like, in a color different from that of the portion adjacent to marker layer 12. Therefore, a boundary between marker layer 12 and the portion adjacent to marker layer 12 can be seen more clearly. Thus, the epitaxial growth amount on a surface of marker layer 12 can be measured by measuring a distance from an uppermost surface of base material 11 after the epitaxial growth treatment described above to the surface of marker layer 12. Further, the epitaxial growth amount in a concave portion of base material 11 can also be obtained by measuring a size of concaves and convexes at base material 11 before the epitaxial growth treatment described above beforehand. Furthermore, the epitaxial growth amount on the surface of marker layer 12 can be compared with the epitaxial growth amount in a concave portion of base material 11.

Consequently, in Embodiment 6 as another example of the cross section observation method according to the present invention, whether or not the epitaxial growth treatment has been appropriately performed on base material 11 can be determined more accurately and easily, by observing the vertical cross section of the sample, based on a difference in growth rate due to a difference in impurity concentration.

### Embodiment 7

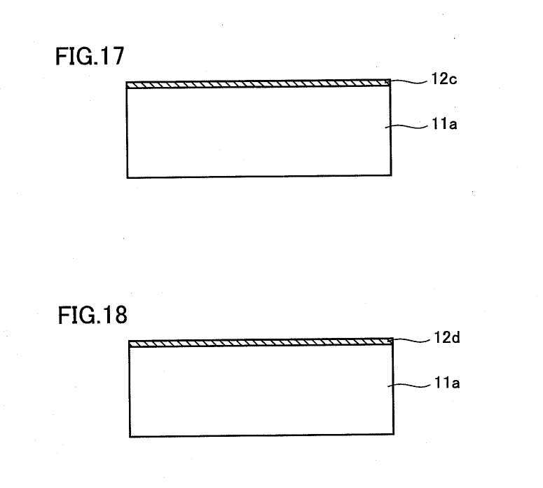

Hereinafter, Embodiment 7 as another example of the cross section observation method according to the present invention will be described with reference to FIG. 17. Embodiment 7 is characterized in that the marker layer is formed at the base material to have a conductivity type different from that of an adjacent region adjacent to the marker layer.

Firstly, as shown in the schematic cross sectional view of FIG. 17, for example, a marker layer 12c having a p-type conductivity type is formed at a top surface of a base material 11 a made of a semiconductor crystal having an n-type conductivity type.

Here, marker layer 12c can be formed, for example, by implanting ions of a p-type dopant in the top surface of base material 11a under conditions that enable the ions of the p-type dopant to be implanted in the top surface of base material 11a made of the n-type semiconductor crystal, and the portion in which the ions of the p-type dopant are implanted can serve as marker layer 12c.

Next, base material 11a in which marker layer 12c described above is formed is subjected to annealing treatment. Thereby, a sample is formed.

Subsequently, as in Embodiments 1 to 6, electrons are emitted to a vertical cross section of the sample, and secondary electrons generated by the emission of the electrons are detected by a secondary electron detector. By performing this step on the entire observation area of the vertical cross section of the sample using, for example, a SEM or the like, the vertical cross section of the sample is observed.

Here, if marker layer 12c has sublimed by the annealing described above, the thickness of marker layer 12c is reduced or marker layer 12c itself disappears. In contrast, if marker layer 12c has not sublimed by the annealing described above, marker layer 12c remains with the thickness maintained.

Further, since marker layer 12c has a conductivity different from that of a portion of base material 11a adjacent to marker layer 12c, marker layer 12c is displayed for example in a SEM image or the like, in a color different from that of the portion of base material 11a adjacent to marker layer 12c. Therefore, a boundary between marker layer 12c and the portion of base material 11a adjacent to marker layer 12c can be seen more clearly. Hence, whether or not marker layer 12c has sublimed by the annealing described above can be determined accurately and easily, and thus, for example, whether or not the annealing treatment has been appropriately performed to an extent not causing sublimation of base material 11a can be determined accurately and easily.

Consequently, in Embodiment 7 as another example of the cross section observation method according to the present invention, whether or not the annealing treatment has been appropriately performed can be determined more accurately and easily, by observing the vertical cross section of the sample.

Although a case where base material 11a has an n-type conductivity type and marker layer 12c has a p-type conductivity type has been described in the foregoing, the present invention is not limited thereto, and base material 11a may have a p-type conductivity type and marker layer 12c may have an n-type conductivity type.

Further, in the present invention, for example, nitrogen, phosphorus, or the like can be used as an n-type dopant, and, for example, aluminum, boron, or the like can be used as a p-type dopant.

### Embodiment 8

Hereinafter, Embodiment 8 as another example of the cross section observation method according to the present invention will be described with reference to FIG. 18. Embodiment 8 is characterized in that the marker layer is formed to have a conductivity type identical to that of an adjacent region adjacent to the marker layer, and have a dopant concentration not less than ten times a dopant concentration in the adjacent region adjacent to the marker layer.

Firstly, as shown in the schematic cross sectional view of FIG. 18, for example, a marker layer 12d having an n-type conductivity type is formed at the top surface of base material 11a made of a semiconductor crystal having an n-type conductivity type. Here, marker layer 12d can be formed, for example, by implanting ions of an n-type dopant in the top surface of base material 11a under conditions that enable the ions of the n-type dopant to be implanted in the top surface of base material 11a made of the n-type semiconductor crystal, such that marker layer 12d has an n-type dopant concentration not less than ten times an n-type dopant concentration in base material 11a, and the ion-implanted portion can serve as marker layer 12d.

Here, by setting the n-type dopant concentration in marker layer 12d to not less than ten times the n-type dopant concentration in base material 11a, a difference in conductivity between marker layer 12d and base material 11a adjacent thereto is increased. Thus, in a cross section observation described later performed by detecting secondary electrons and observing with a SEM or the like, a clearer color contrast can be seen between marker layer 12d and base material 11a adjacent thereto. Hence, a boundary between marker layer 12d and base material 11a adjacent thereto can be recognized more clearly.

Next, base material 11a in which marker layer 12d described above is formed is subjected to annealing treatment. Thereby, a sample is formed.

Subsequently, as in Embodiments 1 to 7, electrons are emitted to a vertical cross section of the sample, and secondary electrons generated by the emission of the electrons are detected by a secondary electron detector. By performing this step on the entire observation area of the vertical cross section of the sample using, for example, a SEM or the like, the vertical cross section of the sample is observed.

Also on this occasion, if marker layer 12d has sublimed by the annealing described above, the thickness of marker layer 12d is reduced or marker layer 12d itself disappears. In contrast, if marker layer 12d has not sublimed by the annealing described above, marker layer 12d remains with the thickness maintained.

Further, since marker layer 12d has a conductivity different from that of a portion of base material 11a adjacent to marker layer 12d, marker layer 12d is displayed for example in a SEM image or the like, in a color different from that of the portion of base material 11a adjacent to marker layer 12d. Therefore, a boundary between marker layer 12d and the portion of base material 11a adjacent to marker layer 12d can be seen more clearly. Hence, whether or not marker layer 12d has sublimed by the annealing described above can be determined accurately and easily, and thus, for example, whether or not the annealing treatment has been appropriately performed to an extent not causing sublimation of base material 11a can be determined accurately and easily also in Embodiment 8.

Consequently, also in Embodiment 8 as another example of the cross section observation method according to the present invention, whether or not the annealing treatment has been appropriately performed can be determined more accurately and easily, by observing the vertical cross section of the sample.

Although a case where each of base material 11a and marker layer 12d has an n-type conductivity type has been described in Embodiment 8, the present invention is not limited thereto, and each of base material 11a and marker layer 12d may have a p-type conductivity type.

Further, although a case where the marker layer is formed in a predetermined number has been described in Embodiments 1 to 8 described above, the number of the marker layer formed in the present invention may be one, or may be plural not less than two.

### EXAMPLES

### Example 1

Firstly, Al ions are implanted in an entire top surface of a silicon carbide substrate that contains nitrogen as an n-type dopant in a dopant concentration of 1×10¹⁸ to 1×10¹⁹ atoms/cm³, such that Al as a p-type dopant in a dopant concentration of 1×10²⁰ atoms/cm³ is contained in an area 0.5 μm deep from the top surface of the silicon carbide substrate.

Next, the silicon carbide substrate in which Al ions described above are implanted is cleaved, and a vertical cross section of the silicon carbide substrate exposed by the cleavage is observed using a SEM. Thereby, a boundary between an Al ion-implanted layer at a top surface portion of the silicon carbide substrate in which Al ions are implanted and an internal portion of the silicon carbide substrate in which Al ions are not implanted can be clearly recognized from color contrast in a SEM photo showing a SEM image of the vertical cross section of the silicon carbide substrate.

Subsequently, on the top surface of the silicon carbide substrate in which Al ions described above are implanted, a silicon carbide crystal layer containing nitrogen as an n-type dopant is epitaxially grown.

Thereafter, the silicon carbide substrate on which the silicon carbide crystal layer described above is epitaxially grown is cleaved, and a vertical cross section of the silicon carbide substrate exposed by the cleavage is observed using a SEM. Thereby, a boundary between the Al ion-implanted layer at the top surface portion of the silicon carbide substrate in which Al ions are implanted and the epitaxially grown silicon carbide crystal layer can be clearly recognized from color contrast in a SEM photo showing a SEM image of the vertical cross section of the silicon carbide substrate.

Consequently, from where the above epitaxially grown silicon carbide crystal layer is formed can be clearly recognized from the observation using a SEM described above, and thus the thickness of the epitaxially grown silicon carbide crystal layer can be measured accurately and easily.

### Example 2

Firstly, as in Example 1, Al ions are implanted in an entire top surface of a silicon carbide substrate that contains nitrogen as an n-type dopant in a dopant concentration of 1×10¹⁸ to 1×10¹⁹ atoms/cm³, such that Al as a p-type dopant in a dopant concentration of 1×10²⁰ atoms/cm³ is contained in an area 0.5 μm deep from the top surface of the silicon carbide substrate.

Next, on the top surface of the silicon carbide substrate in which Al ions described above are implanted, a silicon carbide crystal layer containing nitrogen as an n-type dopant is epitaxially grown to have a thickness of about 10 μm.

Subsequently, the silicon carbide substrate on which the silicon carbide crystal layer described above is epitaxially grown is cleaved, and a vertical cross section of the silicon carbide substrate exposed by the cleavage is observed using a SEM. Thereby, the thickness of the epitaxially grown silicon carbide crystal layer is recognized from color contrast in a SEM photo showing a SEM image of the vertical cross section of the silicon carbide substrate.

Then, the above silicon carbide crystal layer is subjected to plasma etching in a gas containing SF₆ gas, for several minutes.

Next, the silicon carbide substrate after the plasma etching is cleaved, and a vertical cross section of the silicon carbide substrate exposed by the cleavage is observed using a SEM. Thereby, the thickness of the silicon carbide crystal layer after the plasma etching described above is recognized again from color contrast in a SEM photo showing a SEM image of the vertical cross section of the silicon carbide substrate.

Thereafter, by subtracting the thickness of the silicon carbide crystal layer after the plasma etching described above from the thickness of the silicon carbide crystal layer before the plasma etching described above, an etching amount etched by the plasma etching described above can be recognized accurately and easily. Further, by dividing the etching amount by plasma etching time, an etching rate of the plasma etching described above can also be recognized more accurately and easily.

### Example 3

Firstly, as in Examples 1 and 2, Al ions are implanted in an entire top surface of a silicon carbide substrate that contains nitrogen as an n-type dopant in a dopant concentration of 1×10¹⁸ to 1×10¹⁹ atoms/cm³, such that Al as a p-type dopant in a dopant concentration of 1×10²⁰ atoms/cm³ is contained in an area 0.5 μm deep from the top surface of the silicon carbide substrate.

Next, the silicon carbide substrate in which Al ions described above are implanted is cleaved, and a vertical cross section of the silicon carbide substrate exposed by the cleavage is observed using a SEM. Thereby, a boundary between an Al ion-implanted layer at a top surface portion of the silicon carbide substrate in which Al ions are implanted and an internal portion of the silicon carbide substrate in which Al ions are not implanted is recognized from color contrast in a SEM photo showing a SEM image of the vertical cross section of the silicon carbide substrate, and thus the thickness of the Al ion-implanted layer is recognized.

Then, the silicon carbide substrate in which Al ions described above are implanted is annealed by being exposed to an Ar (argon) atmosphere at a temperature of 1800° C. for 30 minutes.

Subsequently, the silicon carbide substrate after the annealing described above is cleaved, and a vertical cross section of the silicon carbide substrate exposed by the cleavage is observed using a SEM. Thereby, the thickness of the Al ion-implanted layer after the annealing described above is recognized again from color contrast in a SEM photo showing a SEM image of the vertical cross section of the silicon carbide substrate.

Thereafter, by subtracting the thickness of the Al ion-implanted layer after the annealing described above from the thickness of the Al ion-implanted layer before the annealing described above, an amount of the Al ion-implanted layer that has sublimed by the annealing described above can be recognized accurately and easily. Further, based on the amount of the Al ion-implanted layer that has sublimed, whether or not the Al ion-implanted layer has sublimed can be recognized accurately and easily.

According to the present invention, a cross section observation method capable of more accurately and easily determining whether or not treatment has been appropriately performed, by observing a cross section of a sample, can be provided. Consequently, the present invention has a possibility of being suitably applicable to, for example, a process of manufacturing semiconductor devices.

Although the present invention has been described and illustrated in detail, it is clearly understood that the same is by way of illustration and example only and is not to be taken by way of limitation, the scope of the present invention being interpreted by the terms of the appended claims.

1. A cross section observation method, comprising the steps of:
forming a marker layer at a base material, said marker layer having a conductivity different from that of another portion of said base material;
forming a sample, by performing treatment on said base material at which said marker layer is formed;
detecting secondary electrons generated by emitting electrons to a cross section of said sample; and
observing said cross section of said sample based on color contrast between said marker layer and the portion of said base material adjacent to said marker layer in a SEM image of said cross section of said sample,
wherein said treatment is at least one selected from the group consisting of epitaxial growth, annealing, and epitaxial growth and etching.

2. (canceled)

3. The cross section observation method according to claim 1, wherein said marker layer is formed by ion implantation.

4. The cross section observation method according to claim 1, wherein said marker layer is formed by epitaxial growth.

5. The cross section observation method according to claim 1, wherein said marker layer is formed at least one of a top surface and an inside of said base material.

6. The cross section observation method according to claim 1, wherein said marker layer forms a pattern.

7. The cross section observation method according to claim 1, wherein a plurality of said marker layers are formed.

8. The cross section observation method according to claim 1, wherein concaves and convexes are formed at a top surface of said base material before or after said step of forming said marker layer.

9. The cross section observation method according to claim 1, wherein said marker layer is formed to have a conductivity type different from that of an adjacent region adjacent to said marker layer.

10. The cross section observation method according to claim 1, wherein said marker layer is formed to have a conductivity type identical to that of an adjacent region adjacent to said marker layer, and have a dopant concentration not less than ten times a dopant concentration in said adjacent region.
